(19) United States
(12) Patent Application Publication
(10) Pub. No.: US 2024/0275180 A1
(43) Pub. Date: Aug. 15, 2024

(54) PORTABLE ELECTRONIC DEVICE BATTERY CHARGING

(71) Applicant: Cirrus Logic International Semiconductor Ltd., Edinburgh (GB)

(72) Inventors: Jon D. HENDRIX, Wimberley, TX (US); Jeffrey D. ALDERSON, Austin, TX (US); Aleksey S. KHENKIN, Lago Vista, TX (US)

(73) Assignee: Cirrus Logic International Semiconductor Ltd., Edinburgh (GB)

(21) Appl. No.: 18/341,053

(22) Filed: Jun. 26, 2023

Related U.S. Application Data
(60) Provisional application No. 63/485,079, filed on Feb. 15, 2023.

(51) Int. Cl. H02J 7/00; G01R 31/392

(52) U.S. Cl. CPC H02J 7/00036; G01R 31/392; H02J 7/0048; H02J 7/005

(57) ABSTRACT

A method of controlling charging of a battery of a portable electronic device, the method comprising: obtaining a usage metric indicative of usage of the battery over its existing lifetime; determining the charge profile for the battery dependent on the usage metric; and controlling charging of the battery based on the determined charge profile.

### FIELD OF DISCLOSURE

The present disclosure relates in general to battery charging, and in particular to a method of controlling charging of a battery of a portable electronic device and associated apparatuses and systems.

### BACKGROUND

Portable electronic devices are typically powered by batteries and may be referred to as battery-powered devices. Example portable electronic devices include cellphones, laptops, tablet computes, wearable electronic devices and power tools. Such devices may be referred to as consumer devices. Batteries for such portable electronic devices may comprise one or more battery cells, and references herein to such batteries may be considered references to the battery cell or cells concerned.

Typical portable electronic devices comprise an onboard charger for controlling charging of their battery, with power being provided from an external power supply such as an external battery or mains power supply via a wired or wireless connection. The onboard charger may monitor battery characteristics including temperature, battery terminal voltage VB (such as battery open-circuit voltage OCV) and State-of-Charge (SOC) and control the charging rate of the battery according to a charge profile which is dependent on those characteristics.

Lithium (Li) batteries, as an example, are typically charged at different charge rates depending on the temperature of the battery and on how full or empty the battery is in terms of charge (i.e. the State-of-Charge, SOC) in order to avoid damaging the battery (the battery cell or cells).

FIG. 1A is a representative example of a typical stepped charge profile for a lithium battery, as may be provided by a battery manufacturer. Such a charge profile may be referred to as a “standard” charge profile, or a datasheet-published charge profile. Such a charge profile may be referred to as a cell charge profile or a battery charge profile. The charge capacity of a battery is the amount of charge the battery can hold. For example, a cellphone battery which can hold 3.2 Ah (3200 mAh) of charge when fully-charged can in theory (ignoring energy losses etc.) discharge from that state at a rate of 3.2 Amps for one hour before the battery has no usable charge remaining. The charge rate (specified for fully re-charging an empty battery) is often referenced to this capacity value, represented as C, where charging a battery at “1 C” means the battery can—in theory—be fully re-charged from empty in 1 hour by means of supplying the number of Amps in the charge capacity numeric value. Thus, for the example 3.2 Ah capacity battery, fully charging the battery (cell) at 1.0 C (i.e. from empty) corresponds to charging it (for 1 hour) at a constant charge rate of 3.2 Amps, fully charging it at 2.0 C corresponds to charging it (for 30 minutes) at a constant charge rate of 6.4 Amps, and fully charging it at 0.5 C corresponds to charging it (for 2 hours) at a constant charge rate of 1.6 Amps.

Turning to FIG. 1A, the example stepped charge profile includes three stepped traces for charge rate (i.e. charging current, in Amps) vs SOC, the lower one for the temperature range 0° C. to 15° C., the middle one for the temperature range 15° C. to 25° C., and the upper one for the temperature range 25° C. to 50° C. The charge rate is given in terms of C as discussed above and the SOC is given in terms of percentage charged, where 0% corresponds to empty and 100% correspond to fully charged. Also, looking at a single trace, the charge profile (charging profile) sets a different allowable limit and/or target charge rate (i.e. charging current, in Amps), given here in units of C, for different ranges of SOC. For example, with the example 3.2 Ah battery, the trace starting at 1.0 C indicates charging (from approx. 0% to 38% SOC) at a charge rate of 3.2 Amps.

FIG. 1B is another representative example of a typical stepped charge profile for a lithium battery, equivalent to that of FIG. 1A but showing charge rate vs battery terminal voltage VB (e.g. OCV). Charge profiles may be defined relative to VB rather than SOC, for example, and the present disclosure will be understood accordingly.

The stepped charge profile of FIG. 1A may be better understood by considering the example charge profile of FIG. 2, which has been simplified to have a single trace (i.e. to ignore temperature) and a single “step”.

In laboratory tests, constant-current constant-voltage (CCCV) charge profiles are typically used for simplicity's sake. Starting with an empty battery/cell, a charger following the charge profile of FIG. 2 would provide whatever voltage (above the cell's open circuit voltage) is required to maintain a constant current of charge into the cell, and this corresponds to the constant-current charge region CC as indicated. The example 0.5 C charge rate may thus be considered a target or upper limit, with the charger providing the necessary voltage to aim for this level of current but not exceed it. Once the voltage required to push current reaches some Max Voltage value, as specified by the cell manufacturer (for example, 4.4 Volts), the charger stops raising the voltage to maintain constant-current. This represents the transition point shown in FIG. 2. For the remainder of the charge cycle, the charger maintains the Max Voltage while the current draw gradually decreases and until the current it pushes reaches some pre-determined minimum value (for example, 0.1 C), when charging ceases. This corresponds to the constant-voltage charge region CV as indicated. Together, the constant-current charge region CC and the constant-voltage charge regions CV constitute a constant-current constant-voltage (CCCV) charge profile. Charging may thus be controlled by an algorithm which is defined based on the charge profile, to implement constant-current charge regions CC and constant-voltage charge regions CV as defined.

Multiple current “steps” can be seen in each trace of the charge profile of FIG. 1A, with each successive current step beginning when the cell has reached a pre-determined condition, e.g., a specific voltage at its terminals. The constant-voltage portion is visible at the end of the charge profile, above 80% SOC in this example.

A similar understanding applies to FIG. 1B.

It has been found that existing techniques for charging batteries of portable electronic devices is inefficient. It is desirable to provide improved battery charging, in particular an improved method of charging a battery of a portable electronic device and associated apparatuses and systems.

### SUMMARY

According to a first aspect of the present disclosure, there is provided a method of charging a battery of a portable electronic device, the method comprising: obtaining a usage metric indicative of usage of the battery over its existing lifetime; determining the charge profile for the battery dependent on the usage metric; and controlling charging of the battery based on the determined charge profile.

According to a second aspect of the present disclosure, there is provided a computer-implemented method of determining a charge profile for a battery of a portable electronic device, the method comprising: obtaining a usage metric indicative of usage of the battery over its existing lifetime; and determining the charge profile for the battery dependent on the usage metric.

According to a third aspect of the present disclosure, there is provided charging apparatus for use by a portable electronic device to charge a battery of the portable electronic device, the charging apparatus configured to carry out the method of the above first aspect.

According to a fourth aspect of the present disclosure, there is provided a portable electronic device, comprising the charging apparatus of the above third aspect.

According to a fifth aspect of the present disclosure, there is provided a charging system comprising a portable electronic device and a server communicatively connected to the portable electronic device, the portable electronic device and the server in combination comprising the charging apparatus of the above third aspect.

Corresponding apparatus/device aspects, method aspects, computer program aspects and storage medium aspects are envisaged. Features of one aspect may be applied to another and vice versa.

### BRIEF DESCRIPTION OF THE DRAWINGS

Reference will now be made, by way of example only, to the accompanying drawings, of which:

FIGS. 1A and 1B, mentioned above, are representations of example charge profiles for a lithium battery;

FIG. 2, mentioned above, is a representation of a simplified charge profile useful for understanding the charge profile of FIG. 1;

FIG. 3 is a table of results from laboratory experiments;

FIGS. 4A and 4B each show a representation of two example charge profiles shown on the same graph, useful for understanding the present invention;

FIG. 5 is a flow diagram of a method embodying the present invention, which may be implemented in a portable electronic device;

FIG. 6 is a schematic diagram of a portable electronic device embodying the present invention;

FIG. 7 is a schematic diagram of an example detailed implementation of the onboard charger of FIG. 6;

FIG. 8 is a schematic diagram of a further example detailed implementation of the onboard charger of FIG. 6;

FIG. 9 is a schematic diagram of a portable electronic device embodying the present invention, being a variation of the portable electronic device of FIG. 6; and

FIG. 10 is a schematic diagram of a system embodying the present invention, comprising a portable electronic device and a remote server.

### DETAILED DESCRIPTION

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiments discussed below, and all such equivalents should be deemed as being encompassed by the present disclosure.

By way of introduction, cell manufacturers provide ‘fixed’ recommended charge profiles which are ‘safe’ for all charge cycles over the lifetime of a battery, whether the battery is brand new or old. However, the inventors have found by experimentation that if a battery is fast-charged, for example at rate 2 C, “early” in its lifetime, it suffers more damage than if fast-charging is performed “later” in its lifetime. The battery lifetime here may be understood to correspond to its operational lifetime, i.e. when it is in use (by the end user or consumer) in a portable electronic device, and is being charged and discharged by that portable electronic device.

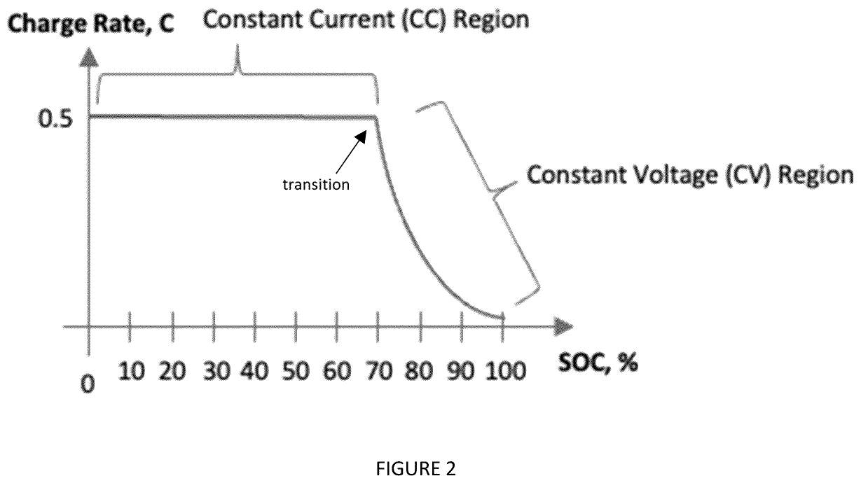

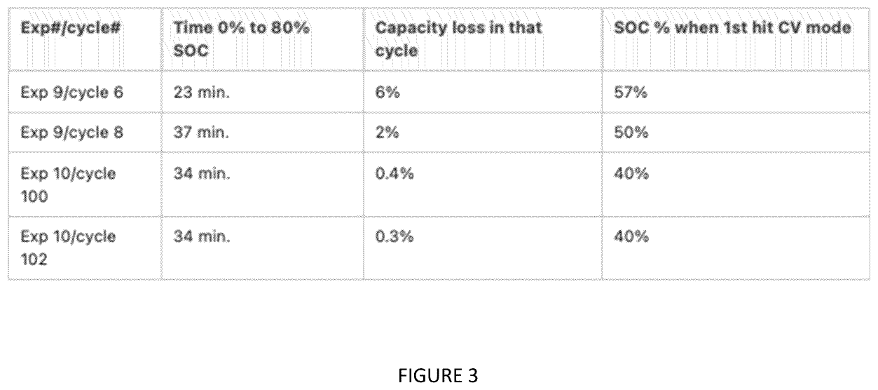

FIG. 3 is a table of results from laboratory experiments carried out on identical ‘fresh’ (brand new) single-cell 3.2 Ah batteries according to the example charge profile of FIG. 2. The results shown relate to two experiments, numbered experiments 9 (Exp 9) and (Exp 10).

For each of experiments 9 and 10, the battery concerned was repeatedly charged (in a charging cycle) from empty up to fully charged according to the charge profile of FIG. 2, and then fully discharged.

In experiment 9, the battery concerned was first subjected to ‘gentle’ charging cycles, comprising one C/2 CCCV conditioning cycle (i.e. the charging profile of FIG. 2 with the CC region at 0.5 C as shown) and with all subsequent charging cycles being aging cycles in which the charging is no faster than C/3 CCCV (i.e. the charging profile of FIG. 2 with the CC region at no higher than C/3), up until charging cycle #6. In charging cycles #6 and #8, the battery was subject to fast charging with a 20 CCCV cycle (i.e. the charging profile of FIG. 2 with the CC region at 2 C), with intermediate charging cycle #7 also being an aging cycle with no faster than C/3 CCCV.

In experiment 10, the battery concerned was similarly first subject to ‘gentle’ charging cycles, comprising one C/2 CCCV conditioning cycle (i.e. the charging profile of FIG. 2 with the CC region at 0.5 C as shown) and with all subsequent charging cycles being aging cycles in which the charging is no faster than C/3 CCCV (i.e. the charging profile of FIG. 2 with the CC region at no higher than C/3), but this time up until charging cycle #100. In charging cycles #100 and #102, the battery was subject to fast charging with a 2 C CCCV cycle (i.e. the charging profile of FIG. 2 with the CC region at 2 C), with intermediate charging cycle #101 also being an aging cycle with no faster than C/3 CCCV.

The results for these experiments shown in FIG. 3 are specifically for the ‘fast’ charging cycles, i.e. cycles #6 and #8 for experiment 9 and cycles #100 and #102 for experiment 10. The results show the time taken for the SOC to increase from 0% to 80% in minutes, the percentage capacity loss of the battery related to that charging cycle, and the SOC when the battery first hit the CV region in that charging cycle. The results could have been presented in terms of VB or OCV, rather than SOC, looking instead at the time for VB or OCV to transition between two defined values corresponding to 0% to 80% SOC.

The capacity loss in a single fast-charge cycle is ˜10× worse in experiment 9 than in experiment 10. One reason for this difference may be some “unfinished cell formation” still occurring early in the battery life, resulting in a greater (detrimental) impact on the battery capacity due to the use of fast-charging earlier in the lifetime in experiment 9 than in experiment 10.

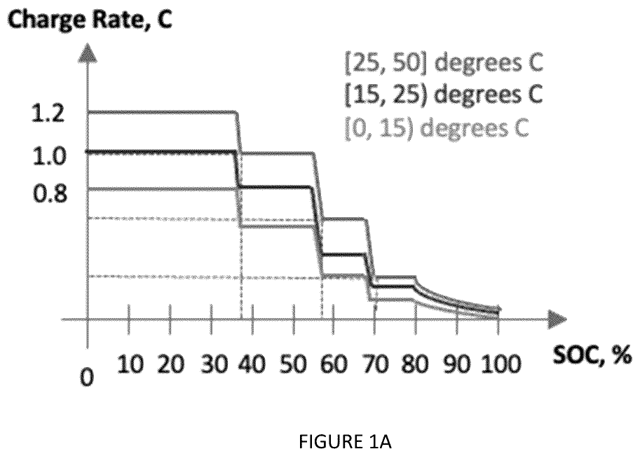

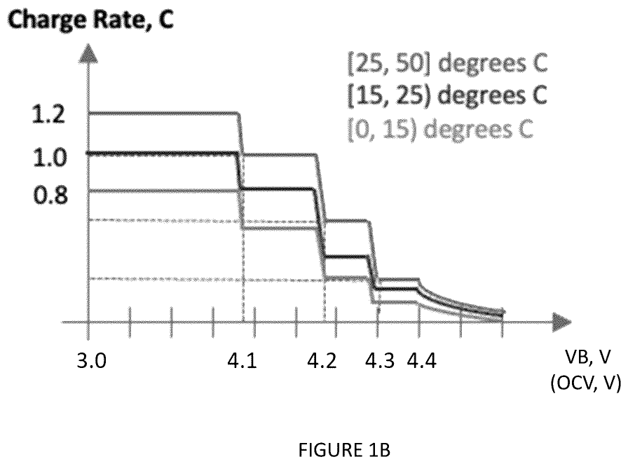

The inventors have determined that, if the charge profile of FIG. 1A/1B (including the different traces for different temperature ranges) is suitable for the full lifetime of the battery (i.e. good for “all time”), and more battery damage/degradation is caused by fast-charging early in the battery lifetime of charging cycles, then it may be possible to exceed the charge rates in the standard manufacture charge profile as shown in FIG. 1A/1B once the battery has been used to a significant degree. This may correspond to the battery having been charged a particular number of times (i.e. once a particular number of full or partial charging cycles have been carried out) and/or a particular charge amount having been passed through the battery, and/or the battery having spent a particular total time duration being charged.

This may allow faster charge times during the majority of the lifetime of the cell, without degrading the battery too much, increasing the overall efficiency of the battery charging. Put another way, a manufacturer's recommended charge profile (such as that shown in FIG. 1A/1B) if followed for the full battery lifetime may be too conservative, avoiding early-life battery (cell) degradation due to fast-charging but missing out on opportunities for faster charging later in the battery lifetime without causing undue battery capacity degradation.

In overview, therefore, the present inventors have considered controlling battery charging in accordance with at least two different charge profiles, dependent on battery usage. In simple terms, this may correspond to using one charge profile for early-life (low battery usage to date) and another charge profile for later-life (high battery usage to date).

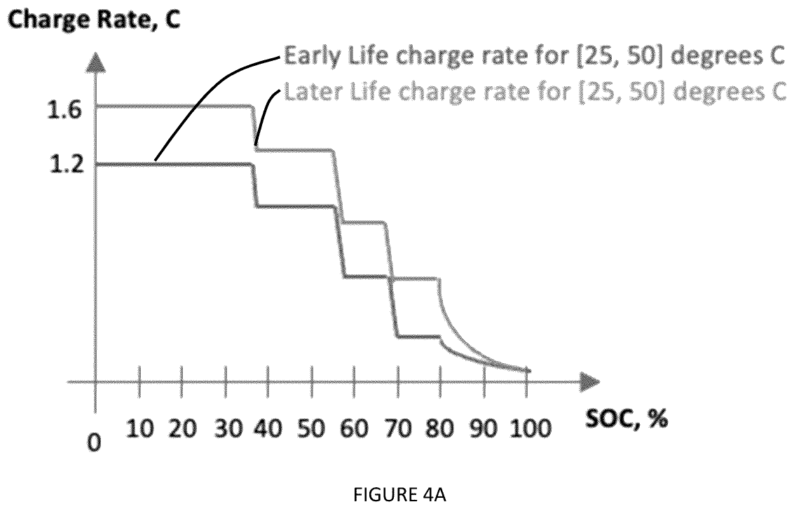

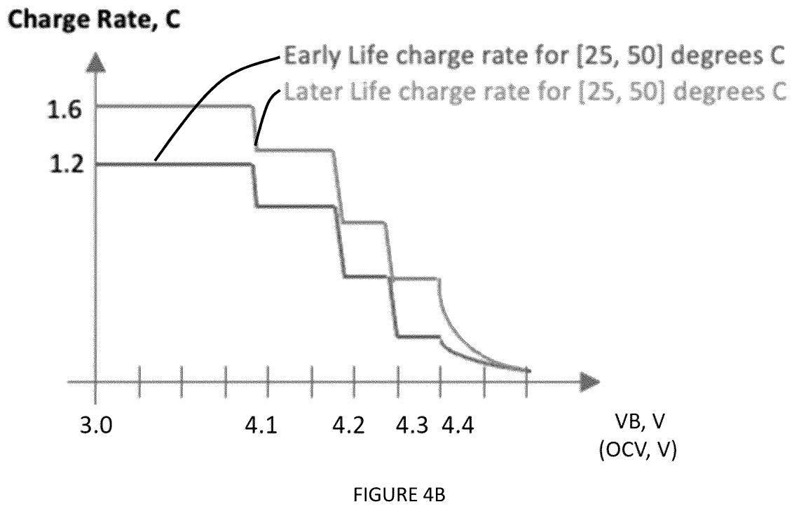

FIG. 4A is an example of two such charge profiles shown on the same graph, each having a single trace for a single example temperature range (here, 25° C. to 50° C.) for simplicity. The early-life trace is the same as the trace for the same temperature range in FIG. 1A for ease of comparison, and starts with a charge rate of 1.2 C. The later-life trace, in contrast, starts with a charge rate of 1.6 C, and represents faster charging of the battery, and thus increased efficiency in battery charging in the later life of the battery.

Similar pairs of traces could be provided for each of the temperature ranges of FIG. 1A, where the early-life trace is the same as in FIG. 1A and the corresponding later-life trace allows for faster charging, or higher charge currents.

It will also be appreciated that more than two traces could be provided for each temperature range, to be used for different portions of battery lifetime, e.g. early-life, mid-life, late-life. It may be, for example, that the charging gets faster over the life of the battery or that charging is faster during the mid-life and is comparatively slower in early-file and late-life (to protect the battery at the beginning and end of its lifetime).

The battery lifetime here may be assumed to be over (corresponding to battery “extinction”) once its storage capacity drops to a given percentage of its original capacity once new, for example to 80%. This would correspond to a battery rated on manufacture as a 3.2 Ah battery dropping to 2.56 Ah in capacity.

FIG. 4B is the same as FIG. 4A but showing the charge profiles in terms of voltage VB or OCV, rather than in terms of SOC, in the same way that FIG. 1B is the same as FIG. 1A but showing the charge profiles in terms of voltage VB or OCV.

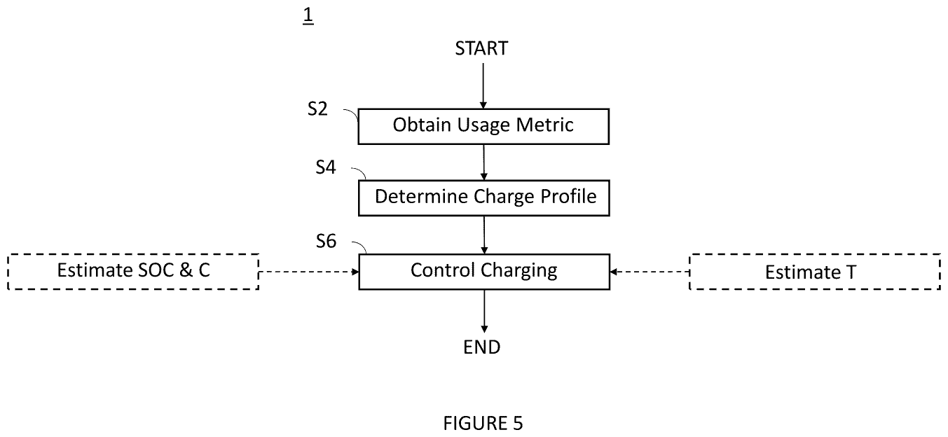

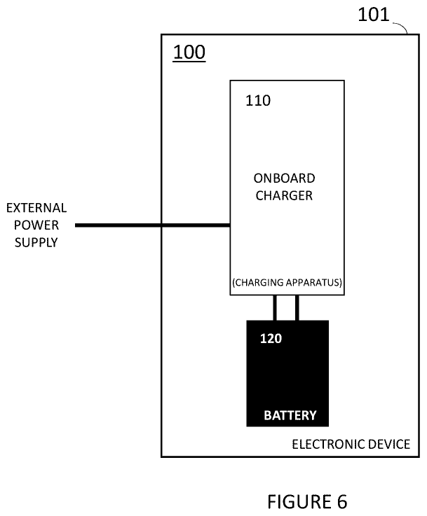

FIG. 5 is a flow diagram of a method 1 embodying the present invention, which may be implemented in a portable electronic device. FIG. 6 is a schematic diagram of such a portable electronic device 100, also embodying the present invention.

Turning first to FIG. 6, the portable electronic device 100 (an electrical or electronic device) may be referred to as a battery-powered device or host device. Example such devices include a mobile telephone, a smartphone, an audio player, a video player, a PDA, a mobile computing platform such as a laptop computer or tablet, a games device, a wearable electronic device and a power tool.

As shown in FIG. 6, the device 100 may comprise an enclosure 101, an onboard charger 110 and a battery 120. The device 100 may be provided without the battery 120 and be fitted with the battery 120 subsequently.

The onboard charger 110 may be referred to as charging apparatus, and is for controlling charging of the battery 120. Power may be provided from an external power supply as indicated (such as an external battery or mains power supply as mentioned earlier) via a wired or wireless connection. The onboard charger 110 may monitor battery characteristics including temperature T, battery capacity C and SOC and control the charging rate of the battery according to a charge profile which is dependent on those characteristics, as explained earlier.

In line with FIGS. 1A/1B and 4A/4B, the onboard charger 110 may monitor VB or OCV, rather than or in addition to SOC. Thus, for all of FIGS. 5 to 10 it will be understood that references to SOC may be replaced with references to VB or OCV, or may be supplemented with references to VB or OCV. For example, the onboard charger 110 may control the charging rate of the battery according to a charge profile which is dependent on VB or OCV, or on a combination of SOC and VB or OCV. For simplicity, going forwards the characteristic SOC will be considered as a running example, but it will be understood that corresponding teaching applies where VB or OCV, or SOC in combination with VB or OCV, is considered.

As considered in more detail later, the onboard charger 110 may keep track of charging and discharging of the battery over an extended period of time (a plurality of charging and/or discharging cycles), for example over the lifetime of the battery.

The enclosure 101 may comprise any suitable housing, casing, chassis or other enclosure for housing the various components of the device 100. Enclosure 101 may be constructed from plastic, metal, and/or any other suitable materials. In addition, enclosure 101 may in some arrangements be adapted (e.g., sized and shaped) such that device 100 is readily transported by a user (i.e. a person).

The onboard charger 110 may be housed within enclosure 101 and may include any system, device, or apparatus configured to control charging of the battery (and optionally other functionality of the device 100).

Control functionality of the onboard charger 110 may be implemented as digital or analogue circuitry, in hardware or in software running on a processor, or in any combination of these. Such control functionality may include any system, device, or apparatus configured to interpret and/or execute program instructions or code and/or process data, and may include, without limitation a processor, microprocessor, microcontroller, digital signal processor (DSP), application specific integrated circuit (ASIC), FPGA (Field Programmable Gate Array) or any other digital or analogue circuitry configured to interpret and/or execute program instructions and/or process data. Thus the code may comprise program code or microcode or, for example, code for setting up or controlling an ASIC or FPGA. The code may also comprise code for dynamically configuring re-configurable apparatus such as re-programmable logic gate arrays. Similarly, the code may comprise code for a hardware description language such as Verilog™ or VHDL. As the skilled person will appreciate, the code may be distributed between a plurality of coupled components in communication with one another. Where appropriate, such aspects may also be implemented using code running on a field-(re)programmable analogue array or similar device in order to configure analogue hardware. Processor control code for execution may be provided on a non-volatile carrier medium such as a disk, CD- or DVD-ROM, programmed memory such as read only memory (Firmware), or on a data carrier such as an optical or electrical signal carrier. Such control circuitry and may be provided as, or as part of, an integrated circuit such as an IC chip.

Although not shown in FIG. 6, the device 100 may comprise a controller separate from the onboard charger 110, such as an application processor, and may also comprise an input and/or output unit (I/O unit) for interaction with a user of the device 100 and/or with another device, and a memory. The memory may be configured to retain program instructions and/or data for a period of time, e.g. for the controller or the onboard charger 110. The application processor, if provided, may be configured to generally control operation of the device 100 and may communicate or interact with (or even control) the onboard charger 110.

Returning to FIG. 5, method 1 may be implemented in the onboard charger 110 of the device 100 and comprises steps S2, S4 and S6 as shown.

Method 1 is a method for charging (or controlling charging of) the battery 120 of the device 100, and comprises, in step S2, obtaining a usage metric indicative of usage of the battery 120 over its existing lifetime, in step S4, determining the charge profile for the battery 120 dependent on the usage metric, and, in step S6, controlling charging of the battery 120 based on the determined charge profile. Such a method may be carried out for each charging cycle of the battery 120, or for each of a plurality of charging cycles of the battery 120, and the present disclosure will be understood accordingly.

Focusing on step S2, the usage metric may comprise an age metric indicative of an age of the battery, and/or a lifetime metric indicative of a lifetime status (e.g. lifetime to date) of the battery. Essentially, the usage metric may be indicative of the age of the battery in terms of its usage as regards charging/discharging. The usage metric may or may not correlate closely with the true age of the battery in terms of time since it was manufactured, dependent on how the battery is used. The usage metric may be considered a charging and/or discharging metric, for example a lifetime or multiple-cycle charging and/or discharging metric.

The usage metric may be based on one or more of the following.

As a first example, the usage metric may be based on (or purely based on, i.e. it may be) the number of charging cycles undergone by the battery. The number of charging cycles may be the number of full charging cycles (where the battery is charged from substantially empty to substantially full, or substantially from 0% to 100% SOC), or may be the number of charging cycles in which the battery is charged by a threshold amount (e.g. to increase its SOC by 50 or 80 percentage units where 100% corresponds to fully charged, such as charging from 50% to 100% SOC, or from 10% to 90% SOC), or may be the number of charging cycles in which the battery is charged until the battery is charged at least to a threshold amount (e.g. until its SOC is above 50% or 80%), or any combination of these. The specific values here are of course just examples.

As a second example, the usage metric may be based on (or purely based on) the cumulative charge amount passed into the cell during charging in the life of the battery.

For example, in a technique known as coulomb counting, the charging current of the battery may be measured/tracked over time and integrated in order to estimate the cumulative charge amount passed into the cell during charging in the life of the battery, and thus evaluate the usage metric.

As a third example, similar to the second example, the usage metric may be based on (or purely based on) the cumulative charge amount passed out of the cell during discharging in the life of the battery. For example, again in a technique known as coulomb counting, the discharging current of the battery may be measured/tracked over time and integrated in order to estimate the cumulative charge amount passed out of the cell during charging in the life of the battery, and thus evaluate the usage metric.

As a fourth example, the usage metric may be based on (or purely based on) the cumulative (or total) length of time spent charging in the life of the battery. Again, the charging current of the battery may be measured/tracked over time, and thus used to estimate the cumulative length of time spent charging in the life of the battery, and thus evaluate the usage metric. Unlike discharge current, which is highly stochastic and may vary by orders of magnitude depending on usage, the charge current is usually tightly defined by the charger so that it does not vary nearly as much. Therefore, a total or cumulative time spent charging a battery/cell may be used as an approximate measurement of its usage, i.e., as the usage metric.

As a fifth example, similar to the fourth example, the usage metric may be based on (or purely based on) the cumulative length of time spent discharging in the life of the battery. The discharging current of the battery may be measured/tracked over time, and this used to estimate the cumulative length of time spent discharging in the life of the battery, and thus evaluate the usage metric.

Effectively, the usage metric may be evaluated by tracking the charging and/or discharging of the battery 120 in some way. The skilled person will be aware of ways to track the charging and/or discharging of the battery 120. As such, in overview, step S2 may comprise tracking the charging and/or discharging of the battery, and determining the usage metric based on the tracked charging and/or discharging.

Considering charge profiles, each charge profile may define allowable limits and/or targets for currents, voltages, and/or charge rates for charging the battery, optionally for or across a full charging cycle of the battery. Such a charge profile may be understood as corresponding to one or more traces similar to those depicted in FIGS. 1A/1B, 2, and 4A/4B. For example, the flat or horizontal portions of such traces may be understood as defining allowable limits and/or targets for charging currents or charge rates, and the transition points at the end of those flat or horizontal portions may be understood as defining allowable limits and/or targets for charging voltages, in line with the CC and CV regions described earlier.

Looking at an individual trace, and focusing on the running example employing SOC, each charge profile may thus be understood as defining the allowable limits and/or targets in relation to a SOC of the battery. For example, the allowable limits and/or targets change at defined points as the SOC changes along the X-axis (moving rightward towards 100% SOC). Of course, although each trace shown herein considers 0% to 100% SOC, a given charge profile could consider a different range for example 20% to 80% SOC, and the present disclosure will be understood accordingly. It is recalled that corresponding teaching applies where VB or OCV is considered.

Again, looking at an individual trace, each charge profile may be understood as defining the allowable limits and/or targets in relation to the capacity C of the battery 120 or the amount of charge the battery can hold (e.g. 3.2 Ah in the example provided earlier). For example, the charge rates given in FIGS. 1, 2, and 4 are referenced to this capacity value C, as mentioned earlier, i.e. the amount of charge the battery can hold. Thus, the capacity of the battery 120 may be tracked in order to determine, for example, the charging currents defined in relation to C in the charge profiles.

The skilled person will be aware of techniques for estimating the capacity C of the battery 120. Direct measurements for example may refer to some physical battery properties such as the terminal voltage and impedance. Record-keeping estimation methods may use battery charging/discharging current data as an input and involve coulomb counting as mentioned earlier. Machine learning (ML) methods may use trained ML models to predict battery capacity based on one or more inputs, such as battery terminal voltage, discharge current and temperature. Of course, combinations of these techniques may be employed to improve accuracy at the expense of complexity.

Looking at combinations of individual traces, for example as depicted in FIG. 1A, each charge profile may be understood as defining the allowable limits and/or targets in relation to a temperature T of the battery. There may be a trace per temperature or temperature range as suggested in FIG. 1A, or temperature may be used to determine allowable limits and/or targets relative to those explicitly defined by a given single, i.e. representative, trace.

Turning to step S4, determining the charge profile for the battery 120 dependent on (or only on, or solely on) the usage metric may comprise selecting the charge profile from a plurality of candidate charge profiles based on the usage metric.

Here, selecting the charge profile may be understood as involving obtaining a selected one of the candidate charge profiles from storage (i.e. a number of charge profiles may be stored in advance, i.e. they may be predefined), or adjusting a given charge profile to become a selected one of the candidate charge profiles (i.e. the selected profile may be calculated—on-the-fly or when needed—by adjusting a given charge profile), or generating a selected one of the candidate charge profiles based on the usage metric (i.e. the selected profile may be calculated—on-the-fly or when needed—based on rules or logic dependent on the usage metric).

Adjusting a given charge profile based on the usage metric may allow for a more graduated set of charge profiles than accessing a predefined charge profile from storage, for a given storage capacity, at the expensive of complexity in calculating charge profiles. Similarly, calculating a charge profile based on rules or logic may allow for a more graduated set of charge profiles and/or lower storage requirements, at the expensive of complexity in calculating charge profiles.

Looking at FIG. 4A, the plurality of candidate charge profiles may comprise a first candidate charge profile and at least one other candidate charge profile, and the method 1 may comprise, in step S4, selecting the first candidate charge profile when the usage metric is below a threshold and selecting one of the other candidate charge profiles when the usage metric is above the threshold.

This may enable the method 1 to select, for example, between the early-life trace (corresponding to an early-life charge profile) and the later-life trace (corresponding to a later-life charge profile) in FIG. 4A. As can be seen from FIG. 4A, at least one allowable limit and/or target defined by the first candidate charge profile may be lower than a corresponding allowable limit and/or target of the one of the other candidate charge profiles. In the example, this may enable the early-life charge profile (first candidate charge profile) to be more conservative in terms of risking battery degradation than the later-life charge profile (the one of the other candidate charge profiles).

Using the data of FIG. 3 for convenience, the threshold may be set, for example, so that the early-life charge profile is used for the first 50 or 80 or 100 charging cycles and so that the later-life charge profile is used after that point. The threshold may be set such that the usage metric for the battery will be below the threshold for a beginning portion of its lifetime, optionally wherein the beginning portion is less than 25% or less than 10% of its estimated or designed lifetime. The threshold may be set such that the usage metric for the battery will be above the threshold for a majority or more than 50% of its estimated or designed lifetime. These threshold values are of course examples.

It will be recalled, looking at FIG. 4A, that similar pairs of traces could be provided for each of the temperatures ranges of FIG. 1, or for other temperatures/ranges, where the early-life trace/profile is the same as in FIG. 1A and the corresponding later-life trace/profile allows for faster charging, or higher charge currents. This would lead to a set of three early-life traces as in FIG. 1A (which may individually or collectively be referred to as a charge profile), for the three temperature ranges shown, and an additional set of three later-life traces (which may also individually or collectively be referred to as a charge profile).

It may be that the so-called later-life charge profile is not suitable for all of the lifetime of the battery after the switch from the early-life profile. For example, it may be that the battery has early-life, mid-life and late-life portions of its lifetime, and that the later-life charge profile is suitable for the mid-life portion but not the late-life portion of its lifetime. For example, it may be that the battery needs to be charged conservatively (i.e. with comparatively low charging rates or charging currents) during its early-life and late-life portions of its lifetime, and that comparatively high charging rates or charging currents are best used in (only) the mid-life portion of its lifetime.

With this in mind, the method 1 may comprise, in step S4, selecting a second candidate charge profile (as one of the plurality of candidate charge profiles) when the usage metric is above the first threshold (where the above-mentioned threshold may be considered the first threshold), or above the first threshold and below a second threshold higher than the first threshold. For example, the first threshold may define the boundary between early-life and mid-life, and the second threshold may define the boundary between mid-life and late-life.

As before, and in line with FIG. 4A, at least one allowable limit and/or target defined by the first candidate charge profile may be lower than a corresponding allowable limit and/or target of the second candidate charge profile. In the example, this may enable the early-life charge profile (first candidate charge profile) to be more conservative in terms of battery degradation than the later-life charge profile (the second candidate charge profile).

The first and second thresholds may be set such that the usage metric for the battery will be between the first and second thresholds for a majority or more than 50% of its estimated or designed lifetime, and/or above the second threshold for an end portion (late-life portion) of its lifetime. The end portion may be less than 25% or less than 10% of its estimated or designed lifetime. The threshold may be set, for example, so that the first charge profile is used for the first 50 or 80 or 100 charging cycles and so that the second charge profile is used for the subsequent charging cycles but potentially only up until the final 50 or 80 or 100 charging cycles of the estimated total lifetime of the battery in charging cycles. It may be that the estimated total lifetime is defined in advance in terms of a number of charging cycles, or this number may be related to battery capacity C which may be monitored as it degrades.

As mentioned earlier in connection with FIG. 4A, more than two traces could be provided for each temperature range, to be used for different portions of battery lifetime, e.g. early-life, mid-life, late-life. More generally, there may be more than two different charge profiles. It may be, for example, that the charging gets faster over the life of the battery or that charging is faster during the mid-life and is comparatively slower in the early-file and late-life.

With this in mind, the plurality of candidate charge profiles may be considered to comprise (in addition to the first and second charge profiles mentioned above) one or more further candidate charge profiles. In this case, the method 1 may comprise, in step S4, selecting a further candidate charge profile when the usage metric is above the second threshold. As an alternative, the plurality of candidate charge profiles need not comprise one or more further candidate charge profiles; the method 1 may comprise, in step S4, selecting the first candidate charge profile when the usage metric is above the second threshold. That is, the first candidate charge profile may be used in both the early-life and late-life periods of the battery lifetime, with the second candidate charge profile used (only) in the mid-life period.

Where there is a further candidate charge profile which is selected as mentioned above, at least one allowable limit and/or target defined by the selected further candidate charge profile may be lower than a corresponding allowable limit and/or target of said second candidate charge profile, and optionally lower than a corresponding allowable limit and/or target of said first candidate charge profile. For example, it may be that the selected further candidate charge profile is more conservative, considering risk of battery degradation, than the first candidate charge profile. Looking at FIG. 4A, this would correspond to a trace for the further candidate charge profile appearing below the two that are shown, for example having an initial charge rate of 0.6 or 0.8 C.

As above, determining the charge profile for the battery dependent on the usage metric may comprise adjusting a given charge profile based on the usage metric so that at least one allowable limit and/or target defined by the given charge profile is: lower than a first amount when the usage metric is below a first threshold; higher than the first amount when the usage metric is above the first threshold; higher than the first amount when the usage metric is above the first threshold and below a second threshold higher than the first threshold; and/or lower than the first amount, and optionally lower than a second amount (which is lower than the first amount) when the usage metric is above the second threshold.

Turning now to step S6, method 1 proceeds after step S4 to control charging of the battery 120 based on the determined charge profile. This may be the relevant selected charge profile as described above, including a charge profile generated by adjusting a given charge profile or generated based on rules or logic.

Looking at FIG. 1A, focusing on the running example employing SOC, controlling charging based on the determined charge profile may comprise estimating SOC so that the position on the relevant trace is known, and estimating battery capacity C so that the charging current corresponding to the charge rate (e.g. 1 C) is known. Similarly, controlling charging based on the determined charge profile may comprise estimating battery temperature T so that the relevant trace (or deviation from a given trace) for the temperature may be employed. As such, FIG. 5 indicates that step S6 may take account of estimated/measured SOC, estimated/measured battery capacity C, and estimated/measured battery temperature T. However, it may be that the charge profile is defined in terms of e.g. charging time in seconds (rather than SOC) and/or that the charge profile does not take into account temperature T. As such, in FIG. 5 and similarly in other figures, it is indicated that the estimation of temperature T, state-of charge SOC and/or capacity C is optional. It is also recalled that corresponding teaching applies where VB or OCV is considered instead of, or in combination with, SOC.

The skilled person will be aware of techniques for estimating the capacity C of the battery 120, as mentioned earlier.

The skilled person will similarly be aware of techniques for estimating the temperature T of the battery 120. Direct measurements for example may refer to an actual temperature sensor, however estimates may be made based on e.g. battery voltage and current (perhaps in conjunction with an estimate of ambient temperature, which may itself be taken from an external actual temperature sensor or be received from an external device). ML models may also be used for this purpose, similarly to the estimation of battery capacity C as mentioned earlier.

Similarly, the SOC may be estimated using any of the techniques described above in relation to estimating battery capacity C, for example using coulomb counting and a history of the point at which previous charging cycles have been terminated based on a fully charged determination (e.g. the current in a final CV region of a charge profile drops to a defined minimum value). VB or OCV may also be estimated or measured based on a measurement of potential difference across the terminals of the battery, for example using a voltmeter with no other load connected to the battery terminals.

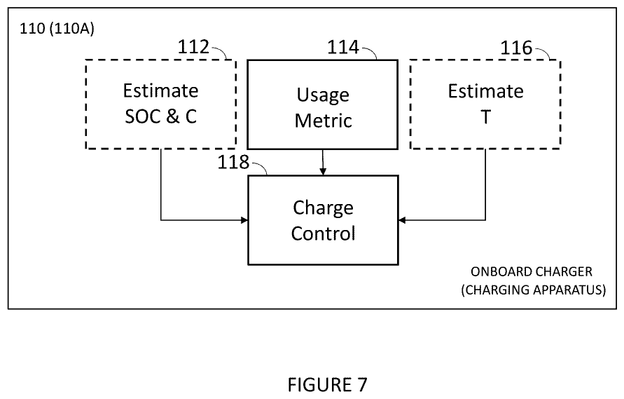

FIG. 7 is a schematic diagram of an example detailed implementation 110A of the onboard charger (charging apparatus) 110, useful for a better understanding of the present invention. As indicated, in the implementation 110A the onboard charger 110 comprises a unit 112 for estimating SOC and battery capacity C (following the running example which considers SOC), a unit 114 for obtaining or determining the usage metric, a unit 116 for estimating battery temperature T, and a unit 118 for controlling battery charging. In line with FIG. 5, units 112 and 116 are indicated as optional, and could for example be replaced by a clock (to measure time).

Units 112 and 116 may be configured to estimate state-of charge SOC, battery capacity C and battery temperature T using any of the techniques mentioned above, or as may be known by the skilled person. Unit 114 may be configured to obtain the usage metric (where it is calculated/stored externally, from elsewhere on the onboard charger 110 or device 100) or to determine the usage metric (where it is calculated locally within the onboard charger 110). The usage metric may be evaluated by tracking the charging and/or discharging of the battery 120 in some way, for example using any of the techniques described above. Unit 118 may then be configured to carry out method 1, or steps S4 and S6 of method 1, obtaining the usage metric from unit 114, and optionally taking into account one or more of the estimated SOC, battery capacity C and battery temperature T.

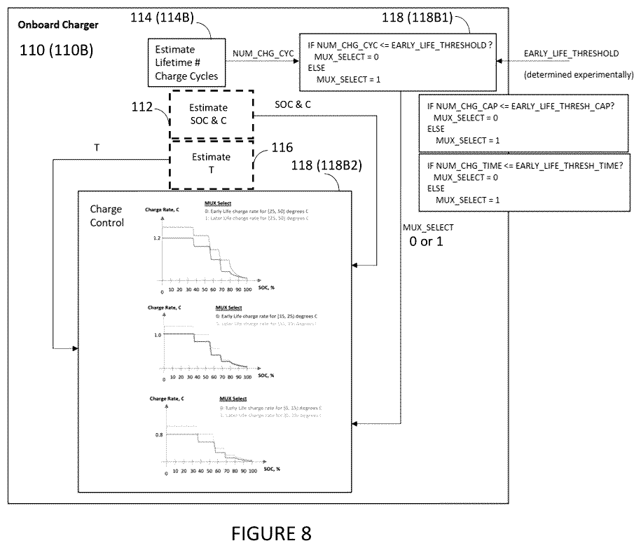

FIG. 8 is a schematic diagram of an example further-detailed implementation 110B of the onboard charger (charging apparatus) 110, useful for a better understanding of the present invention.

As indicated, in the implementation 110B the onboard charger 100 comprises a unit 112 for estimating SOC and battery capacity, a unit 114 for obtaining or determining the usage metric, a unit 116 for estimating battery temperature T, and a unit 118 for controlling battery charging.

These units may be understood in the same way as the corresponding units in the implementation 110A of FIG. 7 and duplicate description will be omitted. In line with FIG. 5, units 112 and 116 are indicated as optional.

Detailed implementations are however shown (following the running example which considers SOC) for units 114 and 118, respectively denoted as 114B and 118B, and these will be described further.

Detailed implementation 114B is configured to calculate the usage metric by estimating the number of charging cycles carried out to date in the lifetime of the battery, by tracking the charging cycles carried out. The output of the unit 114 in this implementation 114B is thus an integer number NUM_CHG_CYC (number of charging cycles), example values of which correspond to the cycles described in connection with the experiments of FIG. 3 (e.g. #6, #8, #100. #102). NUM_CHG_CYC could thus be the usage metric.

In detailed implementation 118B, the functionality of unit 118 is distributed across units 118B1 and 118B2. Unit 118B1 is configured to carry out steps S2 and S4 of method 1, and unit 118B2 is configured to carry out step S6.

In detail, unit 118B1 is configured to obtain the usage metric by receiving the value NUM_CHG_CYC from the unit 114B, corresponding to step S2 of method 1. Unit 118B1 is also configured to receive a threshold value EARLY_LIFE_THRESHOLD by virtue of which to distinguish between the early-life lifetime portion on the one hand and the remaining portion of the lifetime on the other (comprising the mid-life and late-file portions). As such, EARLY_LIFE_THRESHOLD may correspond to the first threshold mentioned earlier. The threshold value EARLY_LIFE_THRESHOLD may have been determined experimentally, e.g. for the particular battery make/model or type concerned, and may be a prestored value.

A more complex embodiment is of course envisaged which makes use of the first and second thresholds mentioned earlier, however for simplicity of explanation the present embodiment is described in relation to a single threshold.

Unit 118B1 is configured to output a MUX_SELECT signal, which has a value 0 or 1, based on the usage metric NUM_CHG_CYC and the threshold value EARLY_LIFE_THRESHOLD. In this example, where NUM_CHG_CYC is less than or equal to EARLY_LIFE_THRESHOLD, the MUX_SELECT signal is assigned the value 0 and otherwise the MUX_SELECT signal is assigned the value 1. That is, where NUM_CHG_CYC is greater than EARLY_LIFE_THRESHOLD, the MUX_SELECT signal is assigned the value 1. For the MUX_SELECT signal, therefore, the value 0 corresponds to a determination that the battery is in its early-life lifetime portion and the value 1 corresponds to a determination that the battery is in the remaining portion of its lifetime (comprising the mid-life and late-life portions, or collectively the later-life portion).

As indicated in FIG. 8, unit 118B2 is configured to receive the MUX_SELECT signal, as well as the state-of-charge SOC, capacity C and temperature T estimates. Based on the MUX_SELECT signal, the unit 118B2 selects the relevant charge profile trace, from the pair traces available for the current temperature T.

For example, if the temperature T is 20° C., the middle pair of traces in FIG. 8 is relevant, and if the MUX_SELECT signal has the value 0, the lower of that pair of traces is selected, which starts at 1.0 C. If the MUX_SELECT signal has the value 1 instead, the upper of that pair of traces is selected.

If the temperature T is 30° C., the upper pair of traces in FIG. 8 is relevant, and if the MUX_SELECT signal has the value 0, the lower of that pair of traces is selected, which starts at 1.2 C. If the MUX_SELECT signal has the value 1 instead, the upper of that pair of traces is selected.

If the temperature T is 10° C., the lower pair of traces in FIG. 8 is relevant, and if the MUX_SELECT signal has the value 0, the lower of that pair of traces is selected, which starts at 0.8 C. If the MUX_SELECT signal has the value 1 instead, the upper of that pair of traces is selected.

Unit 118B2 then controls charging of the battery 120 based on the selected charge profile as described earlier, taking into account the state-of-charge SOC and capacity C to control the charging voltage and/or current as appropriate.

As mentioned earlier, the early-life portion of the battery lifetime may be distinguished from the later-life portion based on the number of times it has been charged/discharged (i.e. once a particular number of full or partial charging cycles have been carried out) and/or a particular charge amount having been passed through the battery, and/or the battery having spent a particular total time duration being charged.

The example usage metric NUM_CHG_CYC as described above relates to the number of charging cycles, however as indicated in FIG. 8 other metrics may be employed as the usage metric such as NUM_CHG_CAP (amount of charge having been passed into the battery during charging) and NUM_CHG_TIME (amount of time spent charging the battery). Moreover, combinations of these metrics may be employed as the usage metric.

For example, where NUM_CHG_CAP is used as the usage metric, this may be output by unit 114B. Unit 114B may calculate this usage metric by estimating the amount of charge passed into the battery in the lifetime of the battery, by tracking the charging. Unit 118B1 may be configured to obtain the usage metric (by receiving NUM_CHG_CAP from the unit 114B) and a corresponding threshold value EARLY_LIFE_THRESH_CAP (equivalent to EARLY_LIFE_THRESHOLD but based on an amount of charge rather than a number of charging cycles). Unit 118B1 may then be configured, where

NUM_CHG_CAP is less than or equal to EARLY_LIFE_THRESH_CAP, to assign the MUX_SELECT signal the value 0 (early-life) and otherwise the value 1 (later-life). Unit 118B2 may then operate as already described.

As another example, where NUM_CHG_TIME is used as the usage metric, this may be output by unit 114B. Unit 114B may calculate this usage metric by estimating the amount of time spent charging in the lifetime of the battery, again by tracking the charging. Unit 118B1 may be configured to obtain the usage metric (by receiving NUM_CHG_TIME from the unit 114B) and a corresponding threshold value EARLY_LIFE_THRESH_TIME (equivalent to EARLY_LIFE_THRESHOLD but based on an amount of time spent charging rather than a number of charging cycles). Unit 118B1 may then be configured, where NUM_CHG_TIME is less than or equal to EARLY_LIFE_THRESH_TIME, to assign the MUX_SELECT signal the value 0 (early-life) and otherwise the value 1 (later-life). Unit 118B2 may then operate as already described.

These are of course just examples, and similar usage metrics and thresholds may be employed where the usage metrics are based on a combination of metrics, e.g. based on numbers of charging cycles and time spent charging. Also, in each example above, more than one threshold may be employed. Taking the usage metric NUM_CHG_CYC as an example, first and second thresholds EARLY_LIFE_THRESHOLD and LATE_LIFE_THRESHOLD may be employed to distinguish between early-life, mid-life and late-life periods, with the MUX_SELECT signal in that case being configured to have one of three corresponding values (e.g. 0, 1, 2). Also in this case, the pairs of traces shown in FIG. 8 may be replaced by groups of three traces, the traces in each group corresponding to the early-life, mid-life and late-life periods, respectively.

It is recalled that the running example considers SOC however the unit 112 may be configured to estimate VB or OCV instead of, or in addition to, SOC in some arrangements. Thus, for example, unit 112 may communicate VB or OCV along with C to unit 118 or 118B2, and the charge profiles concerned may be in terms of VB or OCV instead of SOC, in line with FIGS. 1B and 4B.

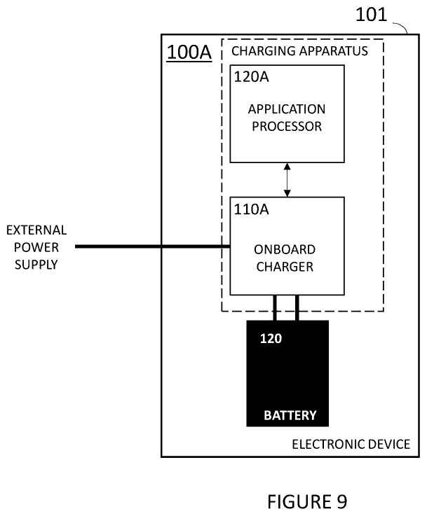

FIG. 9 is a schematic diagram of a portable electronic device 100A, embodying the present invention, which may be considered a variation of the portable electronic device 100. Method 1 of FIG. 5 may be implemented in the portable electronic device 100A.

Portable electronic device 100A is the same as portable electronic device 100 except that the functionality of the charging apparatus is distributed between an onboard charger 110A (provided instead of onboard charger 110) and an application processor 120A. As such, duplicate description is omitted.

Application processor 120A may be provided to generally control operation of the portable electronic device 100A, for example to control operation of the onboard charger 110A as well as other components of the portable electronic device 100A (not shown, e.g., for communication, user interfacing, information display, etc.).

Control functionality of the application processor 120A may be implemented as digital or analogue circuitry, in hardware or in software running on a processor, or in any combination of these. Such control functionality may include any system, device, or apparatus configured to interpret and/or execute program instructions or code and/or process data, and may include, without limitation a processor, microprocessor, microcontroller, digital signal processor (DSP), application specific integrated circuit (ASIC), FPGA (Field Programmable Gate Array) or any other digital or analogue circuitry configured to interpret and/or execute program instructions and/or process data. Thus the code may comprise program code or microcode or, for example, code for setting up or controlling an ASIC or FPGA. The code may also comprise code for dynamically configuring re-configurable apparatus such as re-programmable logic gate arrays. Similarly, the code may comprise code for a hardware description language such as Verilog™ or VHDL. As the skilled person will appreciate, the code may be distributed between a plurality of coupled components in communication with one another. Where appropriate, such aspects may also be implemented using code running on a field-(re)programmable analogue array or similar device in order to configure analogue hardware. Processor control code for execution may be provided on a non-volatile carrier medium such as a disk, CD- or DVD-ROM, programmed memory such as read only memory (Firmware), or on a data carrier such as an optical or electrical signal carrier. Such control circuitry and may be provided as, or as part of, an integrated circuit such as an IC chip.

In an example, steps S2 and S4 of method 1 may be implemented in the application processor 120A, and step S6 may be implemented in the onboard charger 110A. The onboard charger 110A may thus control charging of the battery 120, using power provided from an external power supply as indicated and using a charging profile provided by the application processor 120A or selected (or generated/adjusted) within the onboard charger 110A based on a selection signal provided by the application processor 120A. In some arrangements, the charging profile may be held within the application processor 120A with the onboard charger 110A controlling charging of the battery 120 based on instructions received from the application processor 120A.

Of course, steps S2 and S4 may be split/divided between the application processor 120A and the onboard charger 110A in another way. For example, steps S2 and S6 may be implemented in the onboard charger 110A, with step S4 implemented in the application processor 120A. Appropriate communication of information/signals may be provided between the application processor 120A and the onboard charger 110A depending on how the functionality of the charging apparatus (and method 1) is distributed between them.

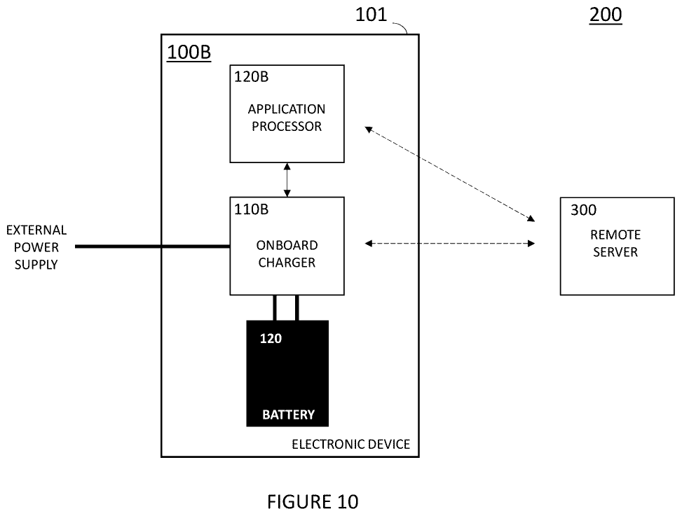

FIG. 10 is a schematic diagram of a system 200, embodying the present invention, comprising a portable electronic device 100B and a remote server (remote computing apparatus) 300. The remote server 300 may be communicatively coupled to the portable electronic device 100B, for example via a network, over wired or wireless communication links. The portable electronic device 100B, itself embodying the present invention, may be considered a variation of the portable electronic device 100A. The remote server 300 may itself embody the present invention.

Method 1 of FIG. 5 may be implemented in the system 200, i.e. by the portable electronic device 100B in combination with the remote server 300.

Portable electronic device 100B is generally the same as portable electronic device 100B, with the application processor 120B and the onboard charger 110B corresponding respectively to the application processor 120A and the onboard charger 110A. As such, duplicate description is omitted. However, the functionality of the charging apparatus may be distributed between the application processor 120B, the onboard charger 110B and the remote server 300. That is, the combination of the application processor 120B, the onboard charger 110B and the remote server 300 may be considered charging apparatus, corresponding to the charging apparatus of FIG. 9 (and FIG. 6).

Control functionality of the remote server 300 may be implemented as digital or analogue circuitry, in hardware or in software running on a processor, or in any combination of these. Such control functionality may include any system, device, or apparatus configured to interpret and/or execute program instructions or code and/or process data, and may include, without limitation a processor, microprocessor, microcontroller, digital signal processor (DSP), application specific integrated circuit (ASIC), FPGA (Field Programmable Gate Array) or any other digital or analogue circuitry configured to interpret and/or execute program instructions and/or process data. Thus the code may comprise program code or microcode or, for example, code for setting up or controlling an ASIC or FPGA. The code may also comprise code for dynamically configuring re-configurable apparatus such as re-programmable logic gate arrays. Similarly, the code may comprise code for a hardware description language such as Verilog™ or VHDL.

As the skilled person will appreciate, the code may be distributed between a plurality of coupled components in communication with one another. Where appropriate, such aspects may also be implemented using code running on a field-(re)programmable analogue array or similar device in order to configure analogue hardware. Processor control code for execution may be provided on a non-volatile carrier medium such as a disk, CD- or DVD-ROM, programmed memory such as read only memory (Firmware), or on a data carrier such as an optical or electrical signal carrier. Such control circuitry and may be provided as, or as part of, an integrated circuit such as an IC chip.

In an example, steps S2 and S4 of method 1 may be implemented in the remote server 300, and step S6 may be implemented in the onboard charger 110B. The onboard charger 110B may thus control charging of the battery 120, using power provided from an external power supply as indicated and using a charging profile provided by the remote server 300 (directly or via the application processor 120B) or selected (or generated/adjusted) within the onboard charger 110B based on a selection signal provided by the remote server 300 (directly or via the application processor 120B). In some arrangements, the charging profile may be held within the application processor 120B or the remote server 300 with the onboard charger 110B controlling charging of the battery 120 based on instructions received from the application processor 120A or the remote server 300.

Of course, steps S2 and S4 may be split/divided between the application processor 120B, the onboard charger 110B, and the remote server 300 in another way. For example, steps S2 and S6 may be implemented in the onboard charger 110A, with step S4 implemented in server 300. Appropriate communication of information/signals may be provided between the application processor 120B, the onboard charger 110B, and the remote server 300 depending on how the functionality of the charging apparatus (and method 1) is distributed between them.

The application processor 120A of FIG. 9, or the application processor 120B and/or the server 300 of FIG. 10, may be configured to carry out a computer-implemented method of determining a charge profile for the battery 120, the method comprising obtaining a usage metric indicative of usage of the battery 120 over its existing lifetime (corresponding to step S2 of method 1), and determining the charge profile for the battery 120 dependent on the usage metric (corresponding to step S4 of method 1). Charging of the battery 120 (corresponding to step S6 of method 1) may be controlled by the onboard charger 110A or 110B based on the determined charge profile.

In some arrangements, the charging apparatus of FIG. 6 or FIG. 9 may be provided separately from other components of the portable electronic device or system concerned. Such charging apparatus, for use by a portable electronic device such as device 100 or 100A to charge its battery 120, may be configured to carry out any of the methods disclosed herein, such as method 1 (or steps thereof). Such charging apparatus may be implemented as a single integrated circuit or as a group of integrated circuits. Any of application processor 120A, application processor 120B, onboard charger 110, onboard charger 110A, and onboard charger 100 may be implemented as a single integrated circuit or as a group of integrated circuits.

The battery 120, as mentioned above, may comprise a battery cell and/or may be a single-cell battery. The battery 120 may comprise a plurality of battery cells. The battery 120 may be a commercially available battery or consumer battery or customer-ready battery or end-user-ready battery. The battery 120 may be a pouch cell or prismatic cell battery. The portable electronic devices disclosed herein may be considered a handheld portable electronic device and/or a mobile electronic device. The portable electronic devices disclosed herein may be considered a consumer device. The skilled person will appreciate that references to a portable electronic device herein could be replaced with references to an electrical or electronic device or system or to a mobile electrical or electronic device or system. Examples of such electronic devices may include cellphones, laptops, tablet computers, wearable electronic devices, power tools, and computing apparatus.

The skilled person will recognise that some aspects of the above-described apparatus (circuitry), devices and methods may be embodied as processor control code, for example on a non-volatile carrier medium such as a disk, CD- or DVD-ROM, programmed memory such as read only memory (Firmware), or on a data carrier such as an optical or electrical signal carrier. For example, any of application processor 120A, application processor 120B, onboard charger 110, onboard charger 110A, and onboard charger 100 may be implemented as a processor operating based on processor control code.

For some applications, such aspects will be implemented on a DSP (Digital Signal Processor), ASIC (Application Specific Integrated Circuit) or FPGA (Field Programmable Gate Array). Thus the code may comprise conventional program code or microcode or, for example, code for setting up or controlling an ASIC or FPGA. The code may also comprise code for dynamically configuring re-configurable apparatus such as re-programmable logic gate arrays. Similarly, the code may comprise code for a hardware description language such as Verilog™ or VHDL. As the skilled person will appreciate, the code may be distributed between a plurality of coupled components in communication with one another. Where appropriate, such aspects may also be implemented using code running on a field-(re)programmable analogue array or similar device in order to configure analogue hardware.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in the claim, “a” or “an” does not exclude a plurality, and a single feature or other unit may fulfil the functions of several units recited in the claims. Any reference numerals or labels in the claims shall not be construed so as to limit their scope.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be understood—especially by those having ordinary skill in the art with the benefit of this disclosure—that the various operations described herein, particularly in connection with the figures, may be implemented by other circuitry or other hardware components. The order in which each operation of a given method is performed may be changed, and various elements of the systems illustrated herein may be added, reordered, combined, omitted, modified, etc. It is intended that this disclosure embrace all such modifications and changes and, accordingly, the above description should be regarded in an illustrative rather than a restrictive sense.

Similarly, although this disclosure makes reference to specific embodiments, certain modifications and changes can be made to those embodiments without departing from the scope and coverage of this disclosure. Moreover, any benefits, advantages, or solutions to problems that are described herein with regard to specific embodiments are not intended to be construed as a critical, required, or essential feature or element. Further embodiments likewise, with the benefit of this disclosure, will be apparent to those having ordinary skill in the art, and such embodiments should be deemed as being encompassed herein.

To aid the Patent Office (USPTO) and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

The present disclosure extends to the following statements:
S1. There is provided a system and method for charging of a battery cell, the system and method arranged to:
   determine an indication of a lifetime status of a battery cell,
   based on the determined lifetime status, adjust a cell charge profile for the battery cell, and
   control charging of the battery cell based on the adjusted cell charge profile.
S2. Preferably, the cell charge profile defines allowable limits for currents, voltages, and/or charge rates for the charging of the battery cell.
S3. Preferably, the cell charge profile is adjusted such that the charging of the battery cell is controlled by a standard cell charge profile for the majority of the cell lifetime; and controlled by a different cell charge profile for a relatively early stage of the battery lifetime and/or for a relatively late stage of the battery lifetime. Alternatively, the cell charge profile may be adjusted such that the charging of the battery cell is controlled by a standard cell charge profile (a standard charge profile, or a datasheet-published charge profile) for a relatively early stage of the battery lifetime and/or for a relatively late stage of the battery lifetime; and controlled by a different cell charge profile for the majority of the cell lifetime.
S4. Preferably, the cell charge profile is selected from a plurality of cell charge profiles based on the determined lifetime status. The cell charge profiles may be retrieved from a memory storage unit provided as part of the system. Alternatively, the cell charge profile is dynamically adjusted based on the determined lifetime status.
S5. Preferably, the indication of a lifetime status is based on one or more of the following: the number of charging cycles undergone by the battery cell; the cumulative charge amount passed into the cell during charging in the life of a cell; the cumulative charge amount passed out of the cell during discharging; and/or the cumulative length of time spent charging in the life of a cell. The system and method is operable to determine the indication of lifetime status according to any of the above-described methods.
S6. Preferably, the cell charge profile is adjusted such that, when the number of charging cycles is below a first threshold, the cell charge profile applies a relatively conservative control of the charging of the battery cell, and when the number of charging cycles is above the first threshold, the cell charge profile applies a relatively regular or standard control of the charging of the battery cell. The first threshold may be used to indicate when the battery cell is in a relatively early stage of the battery life cycle, where cell formation may still be occurring within the cell, such that fast charging is prevented or inhibited to prevent damage to the battery cell. A conservative control may be interpreted as a relatively strict or constrained charging, having lower charge rate limits than a regular or standard battery control. Alternatively, the cell charge profile may be adjusted such that, when the number of charging cycles is below a first threshold, the cell charge profile applies a standard cell charge profile (a relatively conservative control of the charging of the battery cell), and when the number of charging cycles is above the first threshold, the cell charge profile applies a less conservative control of the charging of the battery cell. The first threshold may be used to indicate when the battery cell is in a relatively early stage of the battery life cycle, where cell formation may still be occurring within the cell, such that fast charging is prevented or inhibited to prevent damage to the battery cell. A conservative control may be interpreted as a relatively strict or constrained charging, in line with a regular or standard battery control (a standard charge profile, or a datasheet-published charge profile). A less conservative control may be interpreted as enabling faster charging than specified/permitted by a regular or standard battery control (a standard charge profile, or a datasheet-published charge profile).
S7. Preferably, the cell charge profile is further adjusted such that, when the number of charging cycles is above a second threshold greater than the first threshold, the cell charge profile applies a relatively conservative control of the charging of the battery cell. Such a second threshold may be indicative of a relative late stage of the battery life cycle, where fast charging may be reduced or prevented to preserve remaining cell lifetime.
S8. Preferably, the cell charge profile may be further adjusted based on a monitored battery temperature and/or a monitored battery State of Charge (SOC).
S9. There is further provided an onboard charger device arranged to implement the above-described system and method. The onboard charger device may be provided as a single integrated circuit (IC), or as a group of ICs arranged to be communicatively coupled together.
S10. There is further provided a battery-powered electronic device, such as a cellphone, laptop, tablet computer, wearable electronic device, power tool, wherein the device comprises at least one battery cell and an IC arranged to implement the above-described system and method.
X1. A method of charging (or controlling charging of) a battery of a portable electronic device, the method comprising:
   obtaining a usage metric indicative of usage of the battery over its existing lifetime;
   determining a charge profile for the battery dependent on (or only on) the usage metric; and
   controlling charging of (or charging) the battery based on the determined charge profile.
X2. The method according to statement X1, wherein the usage metric comprises a lifetime metric indicative of a lifetime status of the battery.
X3. The method according to statement X1 or X2, wherein the usage metric is based on, or comprises, one or more of:
   a measure of charging and/or discharging of the battery, or cumulative charging and/or discharging of the battery;
   a measure of charging and/or discharging of the battery over part or all of its existing lifetime;
   the number of charging cycles undergone by the battery, optionally wherein the charging cycles comprise at least one of full charging cycles, charging cycles in which the battery is charged by a threshold amount, and charging cycles in which the battery is charged until the battery is charged at least to a threshold amount;
   the cumulative charge amount passed into the cell during charging in the life of the battery;
   the cumulative charge amount passed out of the cell during discharging in the life of the battery;
   the cumulative length of time spent charging in the life of the battery; and
   the cumulative length of time spent discharging in the life of the battery.
X4. The method according to any of the preceding statements, wherein the usage metric is determined based on tracking the charging and/or discharging of the battery.
X5. The method according to any of the preceding statements, wherein obtaining the usage metric comprises:
   tracking the charging and/or discharging of the battery; and
   determining the usage metric based on the tracked charging and/or discharging.
X6. The method according to any of the preceding statements, wherein:
   each charge profile defines at least one allowable limit and/or target for a current, voltage, and/or charge rate for charging the battery, optionally for or across a full charging cycle of the battery; or
   each charge profile defines a plurality of allowable limits and/or targets for a current, voltage, and/or charge rate for charging the battery, said limits and/or targets for use at different stages in the charging, optionally so that some or all stages in the charging are subject to at least one of the limits and/or targets.
X7. The method according to statement X6, wherein each charge profile defines said at least one allowable limit and/or target in relation to:
   a time spent charging for the charging cycle concerned; and/or
   a potential difference VB across terminals of the battery, such as an open-circuit voltage OCV of the battery; and/or
   a state of charge SOC of the battery; and/or
   a charge capacity C of the battery; and/or
   a temperature T of the battery.
X8. The method according to statement X6 or X7, wherein determining the charge profile for the battery dependent on the usage metric comprises:
   selecting the charge profile from a plurality of candidate charge profiles based on the usage metric, optionally comprising obtaining a selected one of the candidate charge profiles from storage, or adjusting a given charge profile to become a selected one of the candidate charge profiles, or generating a selected one of the candidate charge profiles based on the usage metric; or
   adjusting a given charge profile based on the usage metric.
X9. The method according to statement X8, wherein:
   the plurality of candidate charge profiles comprises a first candidate charge profile and at least one other candidate charge profile; and
   the method comprises selecting the first candidate charge profile when the usage metric is below a threshold and selecting one of the other candidate charge profiles when the usage metric is above the threshold.
X10. The method according to statement X9, wherein:
   at least one allowable limit and/or target defined by the first candidate charge profile is lower than a corresponding allowable limit and/or target of said one of the other candidate charge profiles; and/or
   each allowable limit and/or target defined by the first candidate charge profile is lower than a corresponding allowable limit and/or target of said one of the other candidate charge profiles.
X11. The method according to statement X9 or X10, wherein the threshold is set such that the usage metric for the battery will be:
   below the threshold for (or only for) a beginning portion of its lifetime, optionally wherein the beginning portion is less than 25% or less than 10% of its estimated or designed lifetime; and/or above the threshold for a majority or more than 50% or 75% or 80% or 90% of its estimated or designed lifetime.
X12. The method according to any of statements X9 to X11, wherein:
   the threshold is a first threshold;
   the plurality of candidate charge profiles comprises a second candidate charge profile; and
   the method comprises selecting the second candidate charge profile when the usage metric is above the first threshold, or above the first threshold and below a second threshold higher than the first threshold.
X13. The method according to statement X12, wherein at least one allowable limit and/or target defined by the first candidate charge profile is lower than a corresponding allowable limit and/or target of said second candidate charge profile.
X14. The method according to statement X12 or X13, wherein the first and second thresholds are set such that the usage metric for the battery will be:
   between the first and second thresholds for (or only for) a majority or more than 50% or 80% of its estimated or designed lifetime; and/or
above the second threshold for (or only for) an end portion of its lifetime, optionally wherein the end portion is less than 25% or less than 10% of its estimated or designed lifetime.
X15. The method according to any of statements X12 to X14, wherein:
   the plurality of candidate charge profiles comprises one or more further candidate charge profiles, and the method comprises selecting a further candidate charge profile when the usage metric is above the second threshold; or
   the method comprises selecting the first candidate charge profile when the usage metric is above the second threshold.
X16. The method according to statement X15, wherein at least one (or each) allowable limit and/or target defined by the selected further candidate charge profile is lower than a corresponding allowable limit and/or target of said second candidate charge profile, and optionally lower than a corresponding allowable limit and/or target of said first candidate charge profile.
X17. The method according to any of statements X8 to X16, wherein determining the charge profile for the battery dependent on the usage metric comprises adjusting the given charge profile based on the usage metric so that at least one (or each) allowable limit and/or target defined by the given charge profile is:
   lower than a first amount when the usage metric is below a first threshold; and/or
   higher than the first amount when the usage metric is above the first threshold; and/or
   higher than the first amount when the usage metric is above the first threshold and below a second threshold higher than the first threshold; and/or
   lower than the first amount, and optionally lower than a second amount lower than the first amount, when the usage metric is above the second threshold.
X18. The method according to any of the preceding statements, comprising carrying out said obtaining the usage metric, determining the charge profile and controlling charging of the battery based on the determined charge profile for each charging cycle of the battery, or for each of a plurality of charging cycles of the battery.
X19. A computer-implemented method of determining a charge profile for a battery of a portable electronic device, the method comprising:
   obtaining a usage metric indicative of usage of the battery over its existing lifetime; and
   determining the charge profile for the battery dependent on the usage metric.
X20. A method of charging (or controlling charging of) a battery of a portable electronic device, the method comprising:
   determining a charge profile for the battery according to statement X19; and
   controlling charging of (or charging) the battery based on the determined charge profile.
X21. The method according to any of the preceding statements, wherein:
   the battery comprises a battery cell and/or is a single-cell battery; or
   the battery comprises a plurality of battery cells; or
   the portable electronic device is a handheld portable electronic device and/or a mobile electronic device.
X22. Charging apparatus for use by a portable electronic device to charge (or control charging of) a battery of the portable electronic device, the charging apparatus configured to carry out the method of any of the preceding statements, optionally wherein the charging apparatus is implemented as a single integrated circuit or as a group of integrated circuits communicatively coupled together.
X23. A portable electronic device, comprising the charging apparatus according to statement X22, and optionally comprising the battery.
X24. The portable electronic device of statement X23, being a cellphone, laptop, tablet computer, wearable electronic device, power tool or other personal device.
X25. A charging system comprising a portable electronic device and a server communicatively connected to the portable electronic device, the portable electronic device and the server in combination comprising the charging apparatus according to statement X22, and the portable electronic device optionally comprising the battery.

1. A method of controlling charging of a battery of a portable electronic device, the method comprising:
obtaining a usage metric indicative of usage of the battery over its existing lifetime;
determining a charge profile for the battery dependent on the usage metric; and
controlling charging of the battery based on the determined charge profile.

2. The method according to claim 1, wherein the usage metric is based on, or comprises, one or more of:
a measure of charging and/or discharging of the battery, or cumulative charging and/or discharging of the battery;
a measure of charging and/or discharging of the battery over part or all of its existing lifetime;
the number of charging cycles undergone by the battery, optionally wherein the charging cycles comprise at least one of full charging cycles, charging cycles in which the battery is charged by a threshold amount, and charging cycles in which the battery is charged until the battery is charged at least to a threshold amount;
the cumulative charge amount passed into the cell during charging in the life of the battery;
the cumulative charge amount passed out of the cell during discharging in the life of the battery;
the cumulative length of time spent charging in the life of the battery; and
the cumulative length of time spent discharging in the life of the battery.

3. The method according to claim 1, wherein obtaining the usage metric comprises:
tracking the charging and/or discharging of the battery; and
determining the usage metric based on the tracked charging and/or discharging.

4. The method according to claim 1, wherein:
each charge profile defines at least one allowable limit and/or target for a current, voltage, and/or charge rate for charging the battery; or
each charge profile defines a plurality of allowable limits and/or targets for a current, voltage, and/or charge rate for charging the battery, said limits and/or targets for use at different stages in the charging, optionally so that some or all stages in the charging are subject to at least one of the limits and/or targets.

5. The method according to claim 4, wherein each charge profile defines said at least one allowable limit and/or target in relation to:
a time spent charging for the charging cycle concerned; and/or
a potential difference VB across terminals of the battery, such as an open-circuit voltage OCV of the battery; and/or
a state of charge SOC of the battery; and/or
a charge capacity C of the battery; and/or
a temperature T of the battery.

6. The method according to claim 4, wherein determining the charge profile for the battery dependent on the usage metric comprises:
selecting the charge profile from a plurality of candidate charge profiles based on the usage metric, optionally comprising obtaining a selected one of the candidate charge profiles from storage, or adjusting a given charge profile to become a selected one of the candidate charge profiles, or generating a selected one of the candidate charge profiles based on the usage metric; or
adjusting a given charge profile based on the usage metric.

7. The method according to claim 6, wherein:
the plurality of candidate charge profiles comprises a first candidate charge profile and at least one other candidate charge profile; and
the method comprises selecting the first candidate charge profile when the usage metric is below a threshold and selecting one of the other candidate charge profiles when the usage metric is above the threshold.

8. The method according to claim 7, wherein:
at least one allowable limit and/or target defined by the first candidate charge profile is lower than a corresponding allowable limit and/or target of said one of the other candidate charge profiles; and/or
each allowable limit and/or target defined by the first candidate charge profile is lower than a corresponding allowable limit and/or target of said one of the other candidate charge profiles.

9. The method according to claim 7, wherein the threshold is set such that the usage metric for the battery will be:
below the threshold for a beginning portion of its lifetime, optionally wherein the beginning portion is less than 25% or less than 10% of its estimated or designed lifetime; and/or
above the threshold for a majority or more than 50% or 75% or 80% or 90% of its estimated or designed lifetime.

10. The method according to claim 7, wherein:
the threshold is a first threshold;
the plurality of candidate charge profiles comprises a second candidate charge profile; and
the method comprises selecting the second candidate charge profile when the usage metric is above the first threshold, or above the first threshold and below a second threshold higher than the first threshold.

11. The method according to claim 10, wherein at least one allowable limit and/or target defined by the first candidate charge profile is lower than a corresponding allowable limit and/or target of said second candidate charge profile.

12. The method according to claim 10, wherein the first and second thresholds are set such that the usage metric for the battery will be:
between the first and second thresholds for a majority or more than 50% or 80% of its estimated or designed lifetime; and/or
above the second threshold for an end portion of its lifetime, optionally wherein the end portion is less than 25% or less than 10% of its estimated or designed lifetime.

13. The method according to claim 10, wherein:
the plurality of candidate charge profiles comprises one or more further candidate charge profiles, and the method comprises selecting a further candidate charge profile when the usage metric is above the second threshold; or
the method comprises selecting the first candidate charge profile when the usage metric is above the second threshold.

14. The method according to claim 13, wherein at least one allowable limit and/or target defined by the selected further candidate charge profile is lower than a corresponding allowable limit and/or target of said second candidate charge profile, and optionally lower than a corresponding allowable limit and/or target of said first candidate charge profile.

15. The method according to claim 6, wherein determining the charge profile for the battery dependent on the usage metric comprises adjusting the given charge profile based on the usage metric so that at least one allowable limit and/or target defined by the given charge profile is:
lower than a first amount when the usage metric is below a first threshold; and/or
higher than the first amount when the usage metric is above the first threshold; and/or
higher than the first amount when the usage metric is above the first threshold and below a second threshold higher than the first threshold; and/or
lower than the first amount, and optionally lower than a second amount lower than the first amount, when the usage metric is above the second threshold.

16. The method according to claim 1, comprising carrying out said obtaining the usage metric, determining the charge profile and controlling charging of the battery based on the determined charge profile for each charging cycle of the battery, or for each of a plurality of charging cycles of the battery.

17. A computer-implemented method of determining a charge profile for a battery of a portable electronic device, the method comprising:
obtaining a usage metric indicative of usage of the battery over its existing lifetime; and
determining the charge profile for the battery dependent on the usage metric.

18. Charging apparatus for use by a portable electronic device to control charging of a battery of the portable electronic device, the charging apparatus configured to carry out the method of claim 1.

19. A portable electronic device, comprising the charging apparatus according to claim 18.

20. A charging system comprising a portable electronic device and a server communicatively connected to the portable electronic device, the portable electronic device and the server in combination comprising the charging apparatus according to claim 18.
